(19) United States
(12) Patent Application Publication
(10) Pub. No.: US 2025/0167164 A1
(43) Pub. Date: May 22, 2025

(54) SEMICONDUCTOR PACKAGE

(71) Applicant: Samsung Electronics Co., Ltd., Suwon-si (KR)

(72) Inventors: Jiyeong KIM, Suwon-si (KR); TEA-GEON KIM, Suwon-si (KR); WONGEUN JUNG, Suwon-si (KR); WON CHOI, Suwon-si (KR)

(21) Appl. No.: 18/770,871

(22) Filed: Jul. 12, 2024

(30) Foreign Application Priority Data
Nov. 22, 2023 (KR) 10-2023-0163675

(51) Int. Cl. H01L 23/00; H01L 23/498

(52) U.S. Cl. CPC H01L 24/48; H01L 23/49838; H01L 24/32; H01L 24/45; H01L 24/73; H01L 2224/32225; H01L 2224/45147; H01L 2224/48227; H01L 2224/48496; H01L 2224/48499; H01L 2224/48997; H01L 2224/73265; H01L 2924/18301

(57) ABSTRACT

A semiconductor package may include a substrate, a chip structure on the substrate, a connection pad on the substrate, a connection sheet on the connection pad, and a connection wire electrically connecting the chip structure and the substrate, the connection pad and the connection sheet may include the same material, and a grain boundary may be formed between the connection sheet and the connection pad.

### CROSS-REFERENCE TO RELATED APPLICATIONS

This U.S. non-provisional patent application claims priority under 35 U.S.C. § 119 to Korean Patent Application No. 10-2023-0163675, filed on Nov. 22, 2023, in the Korean Intellectual Property Office, the entire contents of which are hereby incorporated by reference.

### BACKGROUND OF THE INVENTION

The inventive concept relates to a semiconductor package, and more particularly, relates to a semiconductor package including a connection pad and a connection sheet.

A semiconductor package may be provided to implement an integrated circuit chip for use in electronic products. Typically, the semiconductor package includes a semiconductor chip mounted on a printed circuit substrate (e.g., printed circuit board (PCB)). Various components other than semiconductor chip may be combined with a substrate of the semiconductor package. For example, the substrate of the semiconductor package and the semiconductor chip may be electrically connected through a wire.

### SUMMARY

An object of the inventive concept is to provide to a semiconductor package with improved electrical characteristics and reliability.

A semiconductor package according to some embodiments of the inventive concept may include a substrate, a chip structure on the substrate, a connection pad on the substrate, a connection sheet on the connection pad, and a connection wire electrically connecting the chip structure and the substrate, the connection pad and the connection sheet may include the same material, and a grain boundary may be formed between the connection sheet and the connection pad.

A semiconductor package according to some embodiments of the inventive concept may include a substrate, a chip structure on the substrate, a connection pad on the substrate a connection sheet on the connection pad, and a connection wire electrically connecting the chip structure and the substrate, the connection pad and the connection sheet may include the same material, and the connection sheet may include copper nanofibers.

A semiconductor package according to some embodiments of the inventive concept may include a substrate, a solder pad and a solder ball below the substrate, a die film on the substrate, a semiconductor chip on the die film, a connection pad on the substrate, a connection sheet on the connection pad, and a connection wire electrically connecting the semiconductor chip and the substrate, the connection pad may include copper, the connection sheet may include copper nanofibers, and a grain boundary may be formed between the connection sheet and the connection pad.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view for illustrating a semiconductor package according to example embodiments.

FIG. 2 is a cross-sectional view taken along line A-A′ in FIG. 1.

FIGS. 3A to 3E are enlarged views corresponding to region ‘M’ in FIG. 2 according to example embodiments.

FIGS. 4A and 4B are enlarged views corresponding to region ‘M’ in FIG. 2 according to example embodiments.

FIGS. 5A and 5B are cross-sectional views for illustrating a method of manufacturing a semiconductor package according to example embodiments.

### DETAILED DESCRIPTION

Hereinafter, a semiconductor package according to embodiments of the inventive concept will be described in detail with reference to the drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

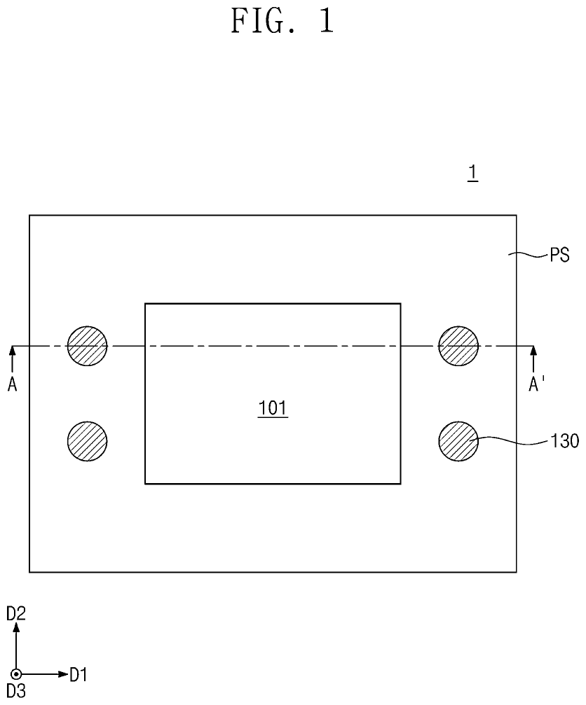

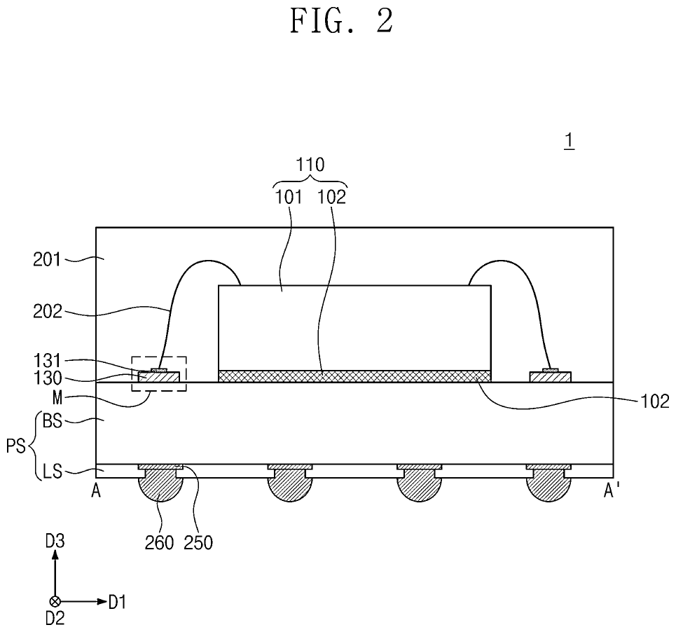

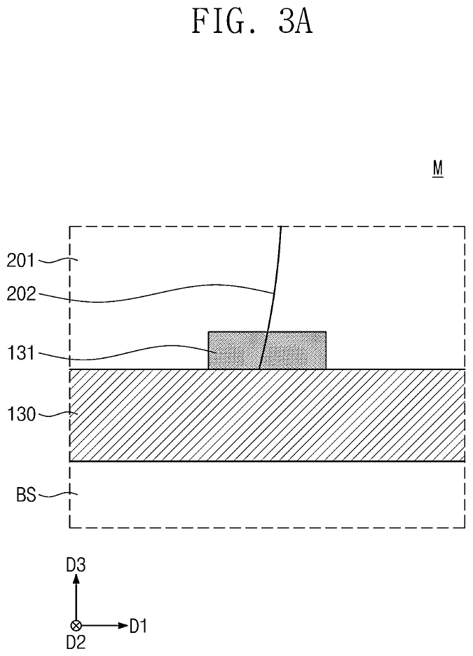

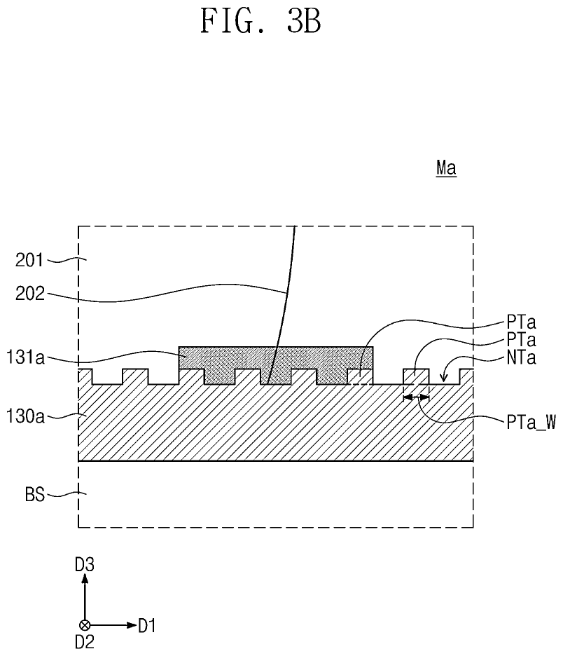

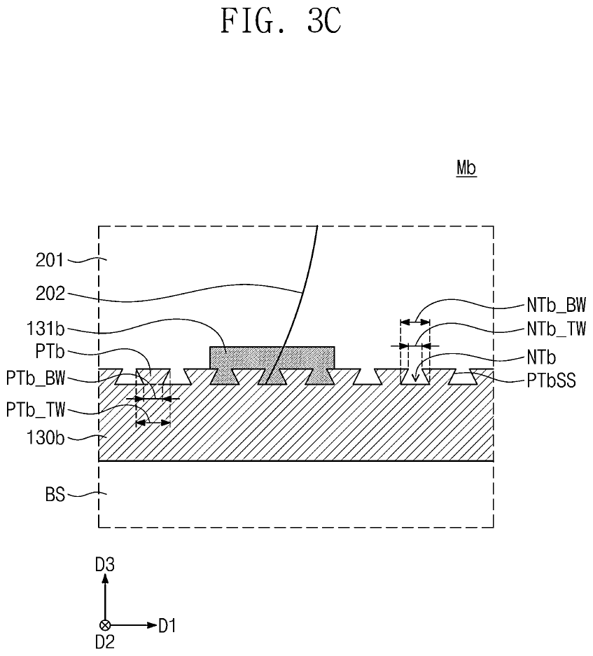

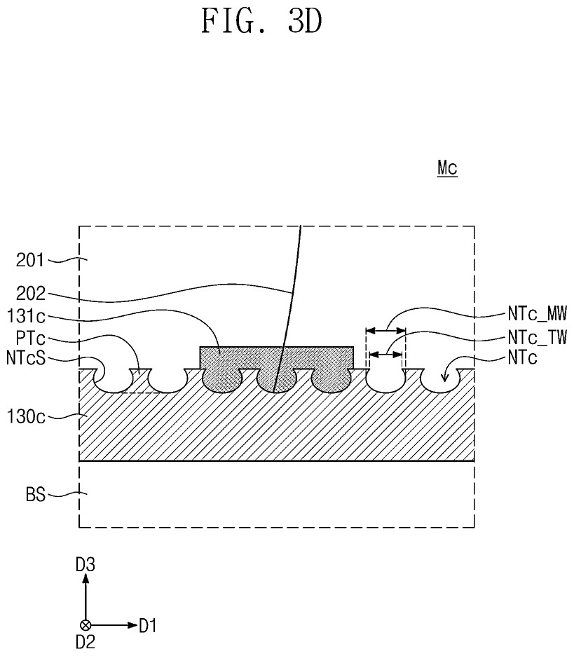

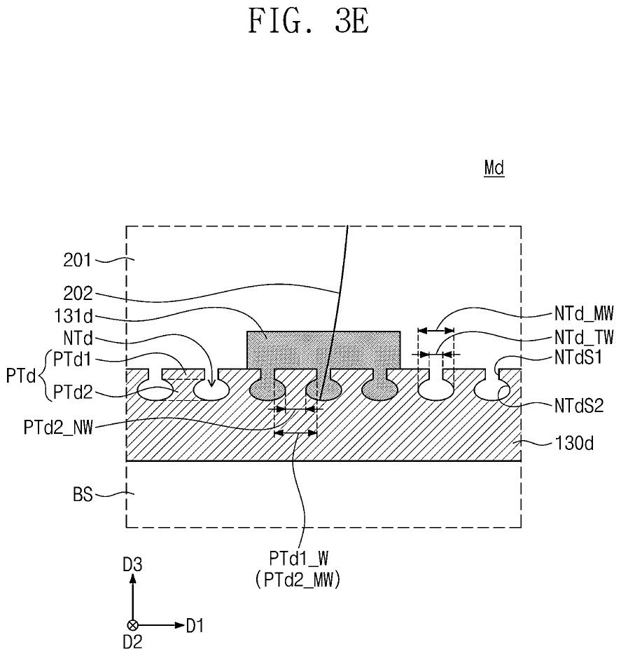

FIG. 1 is a plan view for illustrating a semiconductor package according to example embodiments. FIG. 2 is a cross-sectional view taken along line A-A′ in FIG. 1. FIGS. 3A to 3E are enlarged views corresponding to region ‘M’ in FIG. 2 according to example embodiments.

Referring to FIGS. 1, 2, and 3A, a semiconductor package 1 may include a substrate PS, solder balls 260, solder pads 250 on the solder balls 260, a connection pad 130, a connection sheet 131, a chip structure 110 on the substrate PS, a connection wire 202 connecting the chip structure 110 and the connection sheet 131, and a molding layer 201 on the substrate PS.

The substrate PS may be provided on the solder balls 260 and the solder pads 250. The substrate PS may include a lower insulating layer LS and a base portion BS on the lower insulating layer LS. The substrate PS may connect the chip structure 110 to the outside. For example, the substrate PS may be a printed circuit board (PCB).

The base portion BS may have a plate shape extending along a plane extending in a first direction D1 and a second direction D2. The first direction D1 and the second direction D2 may intersect each other. For example, the first direction D1 and the second direction D2 may be horizontal directions orthogonal to each other. The base portion BS may include an insulating material. For example, the base portion BS may be formed of or include a thermosetting resin such as an epoxy resin, a thermoplastic resin such as polyimide, or a resin impregnated with reinforcing materials such as glass fiber and/or inorganic filler (e.g., prepreg), and/or photocurable resin, etc., but embodiments are not particularly limited thereto.

An insulating layer (not shown) may be additionally disposed on the base portion BS. For example, the substrate PS may be a redistribution substrate including redistribution patterns. The base portion BS may include multiple layers of substrate insulating layers (not shown). The multilayer substrate insulating layers (not shown) may be sequentially stacked in a third direction D3. The third direction D3 may intersect the first direction D1 and the second direction D2. For example, the third direction D3 may be a vertical direction perpendicular to the first direction D1 and the second direction D2.

The lower insulating layer LS may be provided on a lower surface of the base portion BS. The lower insulating layer LS may contact the lower surface of the base portion BS. The lower insulating layer LS may be formed of or include an insulating polymer material. As an example, the lower insulating layer LS may be formed of or include a solder resist material. For example, the solder resist material may be formed of or include epoxy or acrylate. The lower insulating layer LS may protect the base portion BS from the outside. Conductive patterns (not shown) and vias (not shown) may be provided in the base portion BS.

The solder pads 250 may be provided on the lower surface of the base portion BS. The solder pads 250 may contact the lower surface of the base portion BS. The solder pads 250 may be surrounded by the lower insulating layer LS. The lower insulating layer LS may contact side surfaces and at least a portion of a lower surface of the solder pads 250. The solder pads 250 may be in contact with the solder balls 260.

The solder pads 250 may be formed of or include a conductive material. As an example, the solder pads 250 may be formed of or include copper (Cu).

The solder balls 260 may be provided on the solder pads 250. The semiconductor package may be electrically connected to an external device through the solder balls 260. The solder balls 260 may include a conductive material. The solder balls 260 may include solder material. The solder materials may include, for example, tin, bismuth, lead, silver, or alloys thereof.

The solder balls 260 may be connected to solder pads 250. The solder balls 260 may contact the solder pads 250. The solder pads 250 may be connected to vias (not shown) and conductive patterns (not shown) in the substrate PS.

The chip structure 110 may be disposed on the substrate PS. The chip structure 110 may include a die attachment film 102 and a semiconductor chip 101 on the die attachment film 102.

The die attachment film 102 may be provided to secure the semiconductor chip 101 on the base portion BS of the substrate PS. The die attachment film 102 may be disposed on the base portion BS of the substrate PS. The die attachment film 102 may be disposed between the semiconductor chip 101 and the substrate PS. The die attachment film 102 may contact an upper surface of the base portion BS of the substrate PS. The die attachment film 102 may contact a lower surface of the semiconductor chip 101. In one embodiment, the die attachment film 102 may be formed of or include at least one of epoxy resin and rubber resin.

The semiconductor chip 101 may be disposed on the substrate PS. The semiconductor chip 101 may include a semiconductor device. The semiconductor device may be, for example, a logic device. The semiconductor chip 101 may be adhered to the substrate PS through the die attachment film 102.

The connection pad 130 may be provided on the substrate PS. The connection pad 130 may contact an upper surface of the substrate PS. The connection pad 130 may be arranged to be spaced apart from the semiconductor chip 101 in the first direction D1. The connection pad 130 may be formed of or include a conductive material. The connection pad 130 may be formed of or include copper.

The connection sheet 131 may be provided on the connection pad 130. The connection sheet 131 may contact an upper surface of the connection pad 130. The connection sheet 131 may be formed of or include the same material as the connection pad 130 and the connection wire 202. A grain boundary is formed between the connection sheet and the connection pad. The connection sheet 131, the connection pad 130, and the connection wire 202 may be formed of or include, for example, copper. The connection sheet 131 may include copper nanofibers. The connection pad 130, the connection sheet 131, and the connection wire 202 may be electrically connected. The connection pad 130 and the connection sheet 131 may be connected to the semiconductor chip 101 and the connection wire 202. The connection pad 130 and the connection sheet 131 may be electrically connected to the semiconductor chip 101 and the connection wire 202.

Referring to FIG. 3A, a width of the connection sheet 131 may be smaller than a width of the connection pad 130. In example embodiments, when the connection sheet 131 and the connection pad 130 are circular in shape, a diameter of the connection sheet 131 may be smaller than a diameter of the connection pad 130. A width of an upper surface of the connection sheet 131 and a width of a lower surface of the connection sheet 131 may be the same. For example, the connection sheet 131 may have a uniform width.

The molding layer 201 may be provided on the substrate PS. The molding layer 201 may cover at least a portion of an upper surface of the base portion BS of the substrate PS. The molding layer 201 may in contact with exposed upper and side surfaces of the connection pad 130. The molding layer 201 may surround upper and side surfaces of the connection sheet 131. The molding layer 201 may in contact with exposed upper and side surfaces of the connection sheet 131. The molding layer 201 may cover upper and side surfaces of the chip structure 110. The molding layer 201 may surround the connection wire 202. The molding layer 201 may protect the chip structure 110 from external shock and heat.

The molding layer 201 may include an insulating material. As an example, the molding layer 201 may include a polymer material. For example, the polymer material may include epoxy molding compound (EMC), etc.

FIG. 3B is an enlarged view corresponding to region ‘M’ in FIG. 2, which is referred to in FIG. 3B as region “Ma,” according to example embodiments.

Referring to FIG. 3B, in an embodiment, a connection pad 130a may include a protrusion PTa. The protrusion PTa may include a plurality of protrusions PTa. In this case, the protrusion PTa may extend from the connection pad 130a in the third direction D3. A portion of the connection pad 130a that is relatively depressed due to the protrusion PTa may be defined as a depression NTa. The depression NTa may be defined as a depression between the plurality of protrusions PTa.

A width PTa_W of the protrusion PTa may be constant. A width of the upper and lower surfaces of the protrusion PTa may be constant. The connection wire 202 may be disposed on the depression NTa between adjacent protrusions PTa. For example, the connection wire 202 may contact the connection pad 130a on the depression NTa. The connection sheet 131a may fill the depression NTa where the connection wire 202 is disposed. The connection wire 202 may be disposed in the depression NTa, and the connection sheet 131a may fill the depression NTa, thereby improving adhesion between the connection wire 202 and the connection pad 130a.

FIG. 3C is an enlarged view corresponding to region ‘M’ in FIG. 2, which is referred to in FIG. 3C as region “Mb,” according to some example embodiments.

Referring to FIG. 3C, a connection pad 130b may include a protrusion PTb and a depression NTb. The protrusion PTb may include a plurality of protrusions PTb. The plurality of protrusions PTb may extend in a direction perpendicular to the direction in which the substrate PS extends. The plurality of protrusions PTb may be arranged to be spaced apart in the first direction D1. A space between a plurality of adjacent protrusions PTb may be defined as the depression NTb. The depressions toward the inside of the connection pad 130b between the plurality of adjacent protrusions PTb may be defined as the depression NTb. The protrusion PTb may extend from the connection pad 130b in the third direction D3. A width PTb_TW of an upper surface of the protrusion PTb may be greater than a width PTb_BW of a lower surface of the protrusion PTb. A width of the protrusion PTb may decrease in a direction moving from the upper surface of the protrusion PTb to the lower surface of the protrusion PTb. Accordingly, the area of the upper surface of the protrusion PTb may be larger than the area of the lower surface of the protrusion PTb. As an example, the protrusion PTb may have a trapezoidal cross-section with an upper side longer than a lower side.

The depression NTb may include a plurality of depressions NTb, and the plurality of depressions NTb may be defined as depressions from an upper surface of the connection pad 130b toward the inside. The connection wire 202 may be disposed on one of the plurality of depressions NTb. For example, the connection wire 202 may contact the connection pad 130b in the depression NTb. The connection sheet 131b may fill the depression NTb where the connection wire 202 is disposed.

A width NTb_TW of an upper portion of the depression NTb may be defined as a distance between the uppermost portions of adjacent protrusions PTb. A width NTb_BW of a lower portion of the depression NTb may be defined as a distance between the lowermost portions of adjacent protrusions PTb. The width NTb_TW of the upper portion of the depression NTb may be smaller than the width NTb_BW of the lower portion of the depression NTb. A sidewall PTbSS of the protrusion PTb may be inclined.

The connection wire 202 may be provided in the depression NTb, and the connection sheet 131b may fill the depression NTb. The connection wire 202 may be disposed in the depression NTb, and the width NTb_TW of the upper portion of the depression NTb may be smaller than the width NTb_BW of the lower portion of the depression NTb, thereby improving adhesion between the connection wire 202 and the connection pad 130b.

FIG. 3D is an enlarged view corresponding to region ‘M’ in FIG. 2, which is referred to as region “Mc” in FIG. 3D, according to some example embodiments.

Referring to FIG. 3D, a connection pad 130c may include a protrusion PTc and a depression NTc.

The protrusion PTc may include a plurality of protrusions PTc. A space between a plurality of adjacent protrusions PTc may be defined as the depression NTc. The depressions toward the inside of the connection pad 130c between the plurality of adjacent protrusions PTc may be defined as depressions NTc. A surface of the depression NTc may include a curved surface NTcS. The depression NTc may include a curved surface. As an example, the depression NTc having an oval shape with an upper portion partially cut off may be defined as a depression toward the inside of the connection pad 130c. The connection pad 130c may include protrusions PTc remaining between the plurality of depressions NTc. For example, a side surface of the protrusion PTc may have a curved surface.

A width NTc_TW of an upper portion of the depression NTc may be defined as a distance between the uppermost portions of adjacent protrusions PTc. A maximum width NTc_MW of the depression NTc may be defined as a maximum distance among distances between adjacent protrusions PTc. The width NTc_TW of the upper portion of the depression NTc may be smaller than the maximum width NTc_MW of the depression NTc.

The connection wire 202 may be disposed on the depression NTc between adjacent protrusions PTc. For example, the connection wire 202 may contact the connection pad 130c on the depression NTc. The connection sheet 131c may fill the depression NTc where the connection wire 202 is disposed. For example, the connection wire 202 may be disposed in the depression NTc, and the connection sheet 131c may fill the depression NTc, thereby improving adhesion between the connection wire 202 and the connection pad 130c.

FIG. 3E is an enlarged view corresponding to region ‘M’ in FIG. 2, which is referred to as region “Md” in FIG. 3E, according to some example embodiments.

Referring to FIG. 3E, a connection pad 130d may include a protrusion PTd and a depression NTd. The protrusion PTd may be defined as a portion extending from the connection pad 130d toward the molding layer 201.

The protrusion PTd may include a plurality of protrusions PTd. A space between a plurality of adjacent protrusions PTd may be defined as a depression NTd. Depressions toward the inside of the connection pad 130d between the plurality of adjacent protrusions PTd may be defined as depressions NTd.

The protrusion PTd may include a first protrusion PTd1 and a second protrusion PTd2. The first protrusion PTd1 may be defined as a portion of the protrusion PTd that is close to the molding layer 201. The first protrusion PTd1 may be on the second protrusion PTd2. A sidewall of the first protrusion PTd1 may include a flat surface. As an example, the first protrusion PTd1 may have a hexahedral shape.

The second protrusion PTd2 may be defined as a protrusion PTd below the first protrusion PTd1. A side surface of the second protrusion PTd2 may be curved.

The depression NTd may be formed between a plurality of adjacent protrusions PTd. Accordingly, a portion of the depression NTd between the plurality of first protrusions PTd1 may have a flat sidewall, and a portion of the depression NTd between the plurality of second protrusions PTd2 may have a curved sidewall.

In other words, the depression NTd may have a first depression side NTdS1 including a flat surface and a second depression side NTdS2 including a curved surface.

A width PTd1_W of the first protrusion PTd1 may be constant. A minimum width PTd2_NW of the second protrusion PTd2 may be defined as the smallest width among widths of the second protrusion PTd2.

A width PTd1_W of the first protrusion PTd1 may be greater than the minimum width PTd2_NW of the second protrusion PTd2. The width PTd1_W of the first protrusion PTd1 may be equal to a width PTd2_MW of an upper surface of the second protrusion PTd2.

A maximum width NTd_MW of the depression NTd may be defined as the largest distance between adjacent protrusions PTd. The width NTd_TW of the upper portion of the depression NTd may be defined as a distance between the uppermost portions of adjacent protrusions PTd. The maximum width NTd_MW of the depression NTd may be larger than the width NTd_TW of the upper portion of the depression NTd.

The connection wire 202 may be disposed on the depression NTd between adjacent protrusions PTd. For example, the connection wire 202 may contact the connection pad 130d on the depression NTd. The connection sheet 131d may fill the depression NTd where the connection wire 202 is disposed. The connection wire 202 may be disposed in the depression NTd, and the connection sheet 131d may fill the depression NTd, thereby improving adhesion between the connection wire 202 and the connection pad 130d.

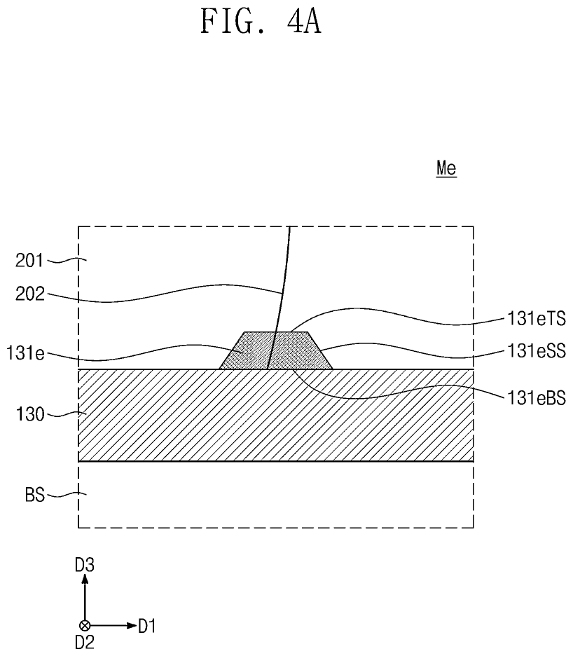

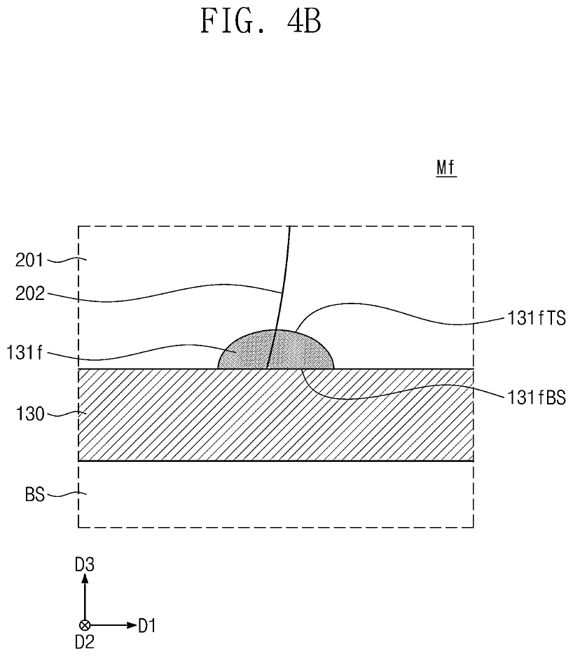

FIGS. 4A and 4B are enlarged views corresponding to region ‘M’ in FIG. 2, which are referred to as region “Me” in FIG. 4A and region “Mf” in FIG. 4B, according to some example embodiments.

Referring to FIG. 4A, in an embodiment, a region of an upper surface 131eTS of a connection sheet 131e may be wider than a region of a lower surface 131eBS of the connection sheet 131e. For example, the connection sheet 131e may have a trapezoidal shape. Although not illustrated, in other embodiments, a width of an upper surface 131eTS of the connection sheet 131e may be smaller than a width of a lower surface 131eBS of the connection sheet 131e.

Referring to FIG. 4B, in an embodiment, an upper surface 131efTS of the connection sheet 131f may include a curved surface, and a lower surface 131efBS of the connection sheet 131f may include a flat surface.

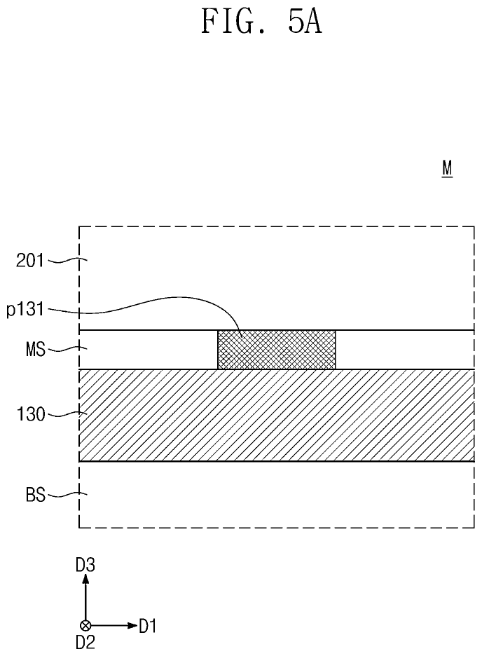

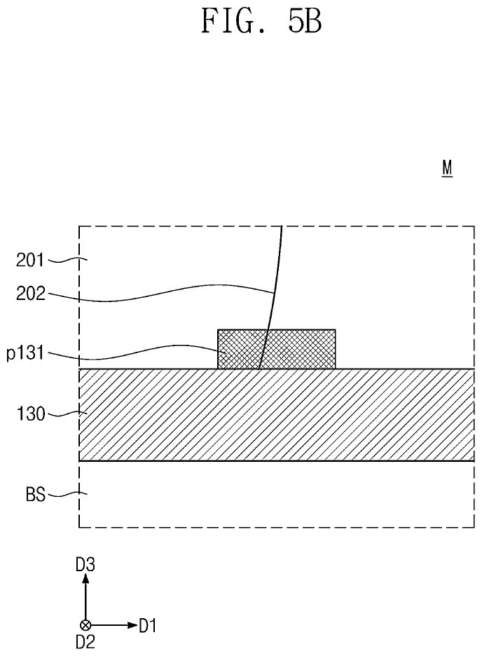

FIGS. 5A and 5B are cross-sectional views for illustrating a method of manufacturing a semiconductor package according to some example embodiments.

Referring to FIG. 5A, a connection pad 130 may be disposed on a base substrate BS on which a chip structure is disposed. Thereafter, a mask pattern MS may be formed on the connection pad 130 to expose a portion where the connection sheet 131 will be formed. A preliminary connection sheet p131 may be applied to the portion exposed by the mask pattern MS. The preliminary connection sheet p131 may be formed of or include copper (Cu) nanofibers. The connection pad 130 may be formed of or include copper.

Referring to FIG. 5B, the mask pattern MS may be removed. After the mask pattern MS is removed, a laser may be irradiated to the preliminary connection sheet p131 on the connection pad 130. In this case, the copper nanofibers of the preliminary connection sheet p131 may be sintered to form the connection sheet 131. A porosity of the connection sheet 131 may be smaller than a porosity of the preliminary connection sheet p131. In this case, a blue laser may be used as the laser. In this case, a wavelength of the laser may be about 450 nm.

As the blue laser is applied, the preliminary connection pad p131 may be heated to a temperature below a melting point of the preliminary connection pad p131, and particles constituting the preliminary connection pad p131, such as copper particles, may solidified in close contact with each other.

The connection wire 202 may be attached to the connection pad 130. When the connection wire 202 is attached, ultrasonic waves may be additionally applied. In this case, the ultrasound waves may be 20 kHz. By applying ultrasonic waves, adhesion between the connection pad 130 and the connection wire 202 may be improved.

Referring again to FIG. 2, the molding layer 201 may be formed on the base substrate BS and the connection pad 130. The solder pads 250 and the solder balls 260 may be formed under the substrate PS. The semiconductor package 1 may be formed.

In the semiconductor package according to embodiments of the inventive concept, the connection wire and the connection pad may be connected through the connection sheet on the connection pad. Accordingly, the adhesion between the connection wire and the connection pad, and even the substrate, may be improved.

In the semiconductor package according to embodiments of the inventive concept, the connection pad may include the depression or the protrusion. As the connection wire is disposed on the depression, the adhesion between the connection wire and the connection pad may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a substrate;
a chip structure on the substrate;
a connection pad on the substrate;
a connection sheet on the connection pad; and
a connection wire electrically connecting the chip structure and the substrate,
wherein the connection pad and the connection sheet include the same material, and
wherein a grain boundary is formed between the connection sheet and the connection pad.

2. The semiconductor package of claim 1, wherein the connection sheet includes copper nanofibers.

3. The semiconductor package of claim 1,
wherein the connection pad includes a plurality of protrusions,
wherein the plurality of protrusions extend from the connection pad in a direction perpendicular to the substrate,
wherein the plurality of protrusions are spaced apart from each other, and
wherein a width of each of the plurality of protrusions is constant.

4. The semiconductor package of claim 1,
wherein the connection pad includes a plurality of protrusions, and
wherein, for each of the plurality of protrusions, a width of an upper surface of the protrusions is greater than a width of a lower surface of the protrusions.

5. The semiconductor package of claim 1,
wherein the connection pad includes a plurality of depressions,
wherein the plurality of depressions are defined as depressions from an upper surface of the connection pad toward an inside of the connection pad, and
wherein the connection wire is disposed on one of the plurality of depressions.

6. The semiconductor package of claim 1,
wherein the connection pad includes a plurality of protrusions spaced apart from each other,
wherein the plurality of protrusions include a first protrusion and a second protrusion,
wherein the first protrusion has a constant width, and
wherein the second protrusion extends from the first protrusion toward an inside of the connection pad, and a side surface of the second protrusion includes a curved surface.

7. The semiconductor package of claim 1,
wherein an upper surface of the connection sheet includes a curved surface, and
wherein a lower surface of the connection sheet includes a flat surface.

8. The semiconductor package of claim 1, wherein a lower surface of the connection sheet is wider than an upper surface of the connection sheet.

9. A semiconductor package comprising:
a substrate;
a chip structure on the substrate;
a connection pad on the substrate;
a connection sheet on the connection pad; and
a connection wire electrically connecting the chip structure and the substrate,
wherein the connection pad and the connection sheet include the same material, and
wherein the connection sheet includes copper nanofibers.

10. The semiconductor package of claim 9, wherein the connection pad, the connection sheet, and the connection wire include copper.

11. The semiconductor package of claim 9, wherein a grain boundary is formed between the connection sheet and the connection pad.

12. The semiconductor package of claim 9,
wherein the connection pad includes a plurality of depressions,
wherein the plurality of depressions are defined as depressions from an upper surface of the connection pad toward an inside of the connection pad, and
wherein the connection wire is disposed on one of the plurality of depressions.

13. The semiconductor package of claim 12,
wherein each depression of the plurality of depressions include:
a first sidewall extending straight from an upper surface of the connection pad to an inside of the connection pad; and
a curved portion connected to the first sidewall, and
wherein the connection wire is in contact with the curved portion of one depression of the plurality of depressions.

14. The semiconductor package of claim 9,
wherein the connection pad includes a plurality of depressions, and
wherein, for each of the plurality of protrusions, a width of the uppermost portion of the depression is smaller than a maximum width of the depression.

15. The semiconductor package of claim 9, wherein a lower surface of the connection sheet is wider than an upper surface of the connection sheet.

16. The semiconductor package of claim 9, wherein the connection sheet includes a connection sidewall between an upper surface of the connection sheet and a lower surface of the connection sheet, and the connection sidewall is inclined.

17. A semiconductor package comprising:
a substrate;
a solder pad and a solder ball below the substrate;
a die attachment film on the substrate;
a semiconductor chip on the die attachment film;
a connection pad on the substrate;
a connection sheet on the connection pad; and
a connection wire electrically connecting the semiconductor chip and the substrate,
wherein the connection pad includes copper,
wherein the connection sheet includes copper nanofibers, and
wherein a grain boundary is formed between the connection sheet and the connection pad.

18. The semiconductor package of claim 17, wherein a width of the connection pad is smaller than a width of the connection sheet.

19. The semiconductor package of claim 17,
wherein the connection pad includes a depression formed inward from an upper surface of the connection pad, and
wherein the connection wire is disposed on the depression.

20. The semiconductor package of claim 19, wherein a side surface of the depression includes a curved surface.
